(19) United States
(12) Patent Application Publication
(10) Pub. No.: US 2023/0093186 A1
(43) Pub. Date: Mar. 23, 2023

(54) SEMICONDUCTOR DEVICE HAVING SOLDER-FREE DIE CONNECTION TO REDISTRIBUTION LAYER

(71) Applicant: Intel Corporation, Santa Clara, CA (US)

(72) Inventors: Tarek A. Ibrahim, Mesa, AZ (US); Rahul N. Manepalli, Chandler, AZ (US); Sairam Agraharam, Chandler, AZ (US); Xiaoxuan Sun, Phoenix, AZ (US)

(21) Appl. No.: 17/479,871

(22) Filed: Sep. 20, 2021

(51) Int. Cl. H01L 23/538; H01L 25/065; H01L 23/00; H01L 21/48

(52) U.S. Cl. CPC H01L 23/5381; H01L 23/5389; H01L 23/5386; H01L 25/0652; H01L 24/24; H01L 24/19; H01L 21/4846; H01L 2924/1432; H01L 2224/24137

(57) ABSTRACT

An electronic device and associated methods are disclosed. In one example, the electronic device includes a semiconductor device. In selected examples, the semiconductor device may include two semiconductor dies, a redistribution layer, an interconnect bridge coupled between the two semiconductor dies and located vertically between the two semiconductor dies and the redistribution layer, and a metallic connection passing through the redistribution layer and coupled to one or more of the two semiconductor dies in a solder-free connection.

### TECHNICAL FIELD

Embodiments described herein generally relate to semiconductor devices. Selected examples include semiconductor die packages having particular features or relationships relating to a die-first packaging process. Still further selected examples include semiconductor die packages including a solder-free die connection or particularly shaped vertical interconnects.

### BACKGROUND

Die packaging is commonly performed in an order that provides for installing or securing the die last or near last with respect to the several layers of the die package that provide for connection to and communication with a motherboard or other semiconductors. That is, for example, a die package for a computer processing unit (CPU) die may historically have included a series of packaging layers below the CPU die with the CPU die being placed last and on top of the other packaging layers. This packaging allows the CPU to be soldered or otherwise secured to a motherboard and/or placed in communication with other types of dies. The communication between the several dies in these circumstances was through substrate routing, for example.

Relatively recent semiconductor packaging concepts include multi-chip packaging where multiple dies are provided in a single package. For purposes of communicatively connecting the several dies within a given chip package, a bridge die has been provided. The bridge die may be arranged below two or more dies in a patch layer and may be used to place multiple dies in communication with one another.

Current approaches to manufacturing multi-chip packages often involve placing redistribution layers on top of the bridge die or patch layer, which can lead to a host of problems. Moreover, placing redistribution layers below the patch layer may involve soldering the bridge die down to the organic redistribution layers and underfilling leaving a solder joint inside the patch layer. This solder may be in addition to the solder used to secure the main dies. This can sometimes force limitations on subsequent reflow thermal budgets based on concerns over multiple reflow cycles and the effect it has on solder.

### BRIEF DESCRIPTION OF THE DRAWINGS

FIG. 1 is a cross-sectional view of a multi-die package secured to a substrate, according to one or more embodiments.

FIG. 2 is a cross-sectional view of the multi-die package of FIG. 1 in isolation from a substrate, according to one more embodiments.

FIG. 3A is a diagram depicting a portion of a method of manufacturing of the multi-die package of FIG. 1 and/or FIG. 2.

FIG. 3B is a diagram depicting a portion of a method of manufacturing of the multi-die package of FIG. 1 and/or FIG. 2.

FIG. 4 is a cross-sectional view of a glass manufacturing substrate with an adhesive film for assembling the multi-die package, according to one or more embodiments.

FIG. 5 is a cross-sectional view of a partially assembled multi-die package including three dies arranged on the glass manufacturing substrate, according to one or more embodiments.

FIG. 6 is a cross-sectional view of a partially assembled multi-die package including an encapsulating material around the three dies, according to one or more embodiments.

FIG. 7 is a cross-sectional view of a partially assembled multi-die package including a passivation layer, according to one or more embodiments.

FIG. 8 is a cross-sectional view of a partially assembled multi-die package showing etching of the passivation layer, according to one or more embodiments.

FIG. 9 is a cross-sectional view of a partially assembled multi-die package including pillars extending from the dies, according to one or more embodiments.

FIG. 10 is a cross-sectional view of a partially assembled multi-die package including a bridge die installed across two of the three dies, according to one or more embodiments.

FIG. 11 is a cross-sectional view of a partially assembled multi-die package including mold and underfill around the pillars and the bridge die, according to one or more embodiments.

FIG. 12 is a cross-sectional view of a partially assembled multi-die package including a dielectric layer with conductor layer vias, according to one or more embodiments.

FIG. 13 is a cross-sectional view of a partially assembled multi-die package including filled and plated vias forming a redistribution circuit, according to one or more embodiments.

FIG. 14 is a cross-sectional view of a partially assembled multi-die package including a photo sensitive passivation layer with plated vias, according to one or more embodiments.

FIG. 15 is a system diagram, according to one or more embodiments.

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

The present application, in one or more embodiments, relates to a particularly structured die package. In particular, the die packaging process may be performed using the die first and building the die package off of the die. As a result, the die may be electrically connected to other aspects of the die package with a sputtered titanium-copper alloy or other alloy in lieu of soldering creating a solder-free electrical pathway connection between the one or more dies and the redistribution layer, for example. Still further, as a result of the “inverted” assembly process, vertical interconnects that extend through one or more portions of the redistribution layer and connect to a bridge die may taper from larger to smaller as the interconnects extend toward the bridge die. Still other structural and/or geometric features may result from the manufacturing process. The die package may be advantageous by providing an architecture with a relatively small bridge and a single bump pitch. In addition, a single solder joint (e.g., between the bridge and the die) may be provided rather than two solder joints (e.g., between the dies and the path as well as between the bridge and the patch). Moreover, a laser process can be used to create the redistribution via to land on the TSV pad.

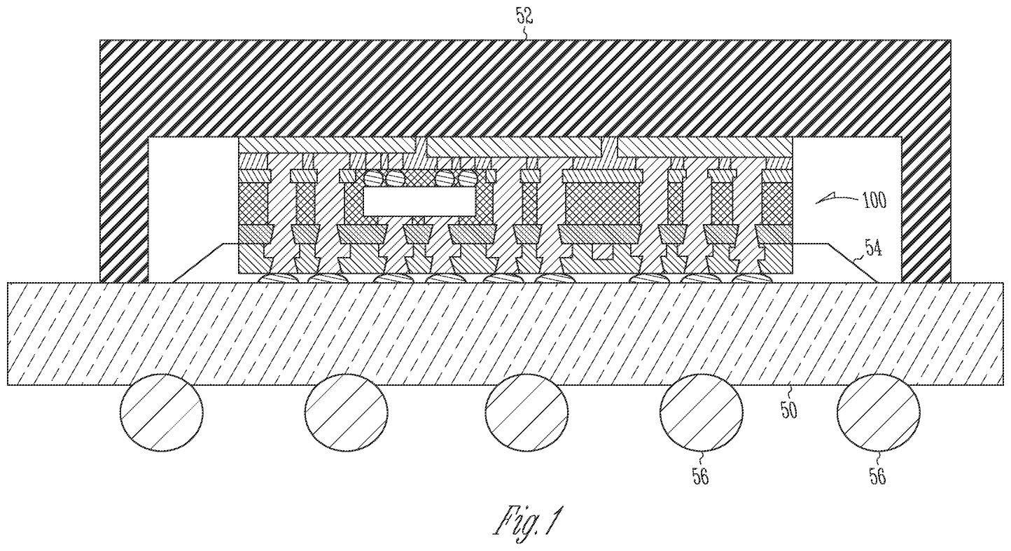

Turning now to FIG. 1, a semiconductor device in the form of a multi-die package 100 is shown secured to a substrate 50 and enclosed with a lid 52. The multi-die package 100 may be thermo compression bonded to the substrate with a ball grid array on the substrate aligned with interconnects on the multi-die package, as shown. An epoxy underfill 54 may be provided to infill around the ball grid array that secures the multi-die package 100 to the substrate 50. An integrated heat spreader lid 52 may encapsulate the multi-die package 100 and a larger ball grid array 56 may be provided on the underside of the substrate 50 for securing the substrate 50 to a motherboard, for example.

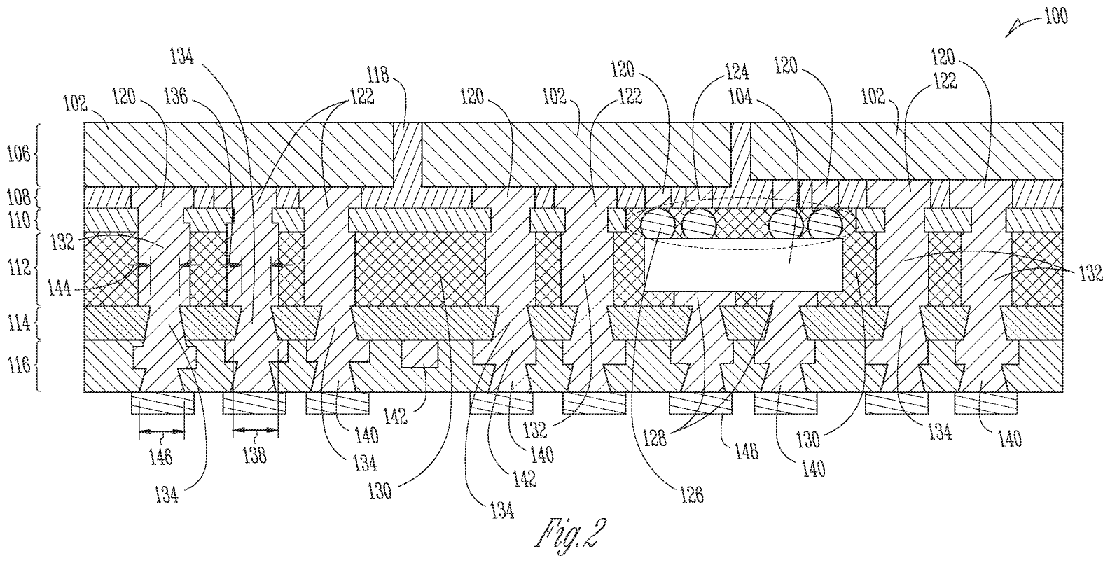

FIG. 2 shows the isolated semiconductor device. The semiconductor device may include a multi-die package 100 that may be manufactured together with a large number of similar or same multi-die packages. That is, the multi-die package 100 may be manufactured in groups and later singulated for being assembled as shown in FIG. 1. The multi-die package 100 may include a central processing unit for a computing device or another type of function may be provided. The functionality of the multi-die package 100 may be determined by one or more dies 102 that are part of the package and the interconnectivity provided by, for example, an interconnect bridge or bridge die 104. As shown in FIG. 2, the multi-die package 100 may include a series of layers with interconnects extending between and/or through one or more layers. The multi-die package 100 may include a die layer 106, a passivation layer 108, a bridge die layer 110, a redistribution layer 111 made up of one or more a dielectric layers 112 and one or more conductor layers 114, and aboard bump layer 116.

While each layer mentioned is described below, one or more layers may be omitted or interchanged depending on design requirements. Moreover, the multi-die package is described in this section based on its in-use orientation shown in FIGS. 1 and 2, where the dies are arranged at the top of the package and the board bump layer is arranged at the bottom.

Beginning with the die layer 106, this layer may be configured to secure the several dies 102 of the package generally in plane with one another and in secured relative positions within the plane. The die layer 106 may include one or more dies 102 that have been manufactured using a photolithographic process or other processes. The one or more dies 102 may be secured in relative positions by an encapsulating material 118 such as, for example, photo imageable dielectric (PID) or silicon nitride with lithographic etch. The encapsulating material 118 may surround the sides and bottom of the dies 102 leaving the top surface of the dies exposed. The dies may include connective bumps 120 on a bottom side thereof that extend downward from the respective dies 102. The connective bumps 120 may be encapsulated by the encapsulating material 118. However, a bottom surface of the bumps 120 may be exposed allowing for connectivity to adjacent components, for example. In one or more embodiments, the connective bumps 120 may be formed at the wafer level (e.g., before separating the wafer into individual dies). The die layer 106 may have a thickness selected to encapsulate the dies 102. As may be appreciated from a review of the manufacturing method discussed below, the electrical connection between the dies 102 in the die layer 106 and the layers below the die layer may be a solder-free connection. That is, for example, the metallic material extending downward from the dies in the die layer may include pillars and vias made of copper, titanium copper, or other conductive metals and may not include any solder connections between the dies and the redistribution layer 111, for example.

The passivation layer 108 may be arranged directly below the die layer 106 between the die layer 106 and the bridge die layer 110. The passivation layer 108 may be configured to provide charge-separation. For example, the passivation layer may reduce the charge recombination at surface states, increase the water oxidation reaction kinetics, and protect the components from chemical corrosion. The passivation layer 108 may be substantially continuous across the bottom side of the die layer 106. However, interconnects or vias 122 may be provided through the passivation layer at one or more bumps 120 of the dies 102 and a clearing 124 in the passivation layer 108 may be provided at a location of a bridge die 104 discussed in more detail below. At the locations of the interconnects 122 and at the clearing 124, a respective portion of the passivation layer 108 may be omitted for the full thickness of the passivation layer 108. In one or more embodiments, the diameter or other crossing dimension of the vias 122 in the passivation layer 108 at the die bumps 120 may be equal to or smaller than the diameter or other crossing dimension of the die bumps 120. The vias 122 in the passivation layer 108 may be filled with a conductor or metal, such as titanium-copper, for example, allowing for electrical communication through the passivation layer 108 at selected locations that are aligned with the die bumps 120.

The bridge die layer 110 may be arranged adjacent to and below the passivation layer 108, between the passivation layer 108 and the dielectric layer 112, and/or between the die layer 106 and the redistribution layer 111. The bridge die layer 110 may include a bridge die 104 and may be configured to secure the bridge die 104 in position below two or more dies 102 in the die layer 106 and in a position to laterally bridge a gap between the two or more dies 102 in the die layer 106. That is, the bridge die 104 may be adapted to overlap (when viewed in plan view) with two or more dies 102 in the die layer 106 and may be arranged vertically between the die layer 106 and the redistribution layer 111 due to its position within the bridge die layer 110. The bridge die 104 may include a ball grid array 126 on a top side and titanium copper pads 128 on a bottom side. The bridge die 104 may, for example, be secured to the two or more dies 102 by way of placement in the clearing 124 of the passivation layer 108 and using thermal compression bonding to secure the bridge die 104 to the dies 102 in the die layer 106 with the ball grid array 126. The bridge die layer 110 may include an encapsulating material 130 that is the same or similar to the encapsulating material 118 used in the die layer 106. In one or more embodiments, a mold material may be used or different encapsulating materials may be used. The encapsulating material 130 may encapsulate the sides of the bridge die 104, the bottom of the bridge die 104, and the top of the bridge die 104. That is, the encapsulating material 130 may be arranged in the clearing 124 of the passivation layer 108 so as to be arranged above the bridge die 104 and may also surround the sides of the bridge die 104 and pass below the bridge die 104. The bridge die layer 110 may also include pillars 132 extending through the bridge die layer 110. The pillars 132 may be aligned with the vias 122 in the passivation layer 108. Both the pillars 132 and the copper pads 128 on the bottom side of the bridge die 104 may be exposed on a bottom side of the bridge die layer 110. Like the die layer 106, the bridge die layer 110 may have a thickness adapted to encapsulate the bridge die 104 as mentioned.

The redistribution layer 111 may be arranged below the bridge die layer and may be adapted for redistributing electrical circuit pathways, for example. That is, due to the in-plane nature of the circuitry, one or more redistribution layers may be used to allow for circuitry pathways that cross over one another without creating short circuits. In one or more embodiments, the redistribution layers may each include a dielectric layer 112 and a conductor layer 114.

The dielectric layer 112 may be arranged directly below the bridge die layer 110. The dielectric layer may be configured to provide separation between conductor layers. That is, for example, while a single dielectric layer 112 and a single conductor layer 114 has been shown, multiples of each of these layers may be provided to allow for distribution of conductive paths. In one or more embodiments, the dielectric layer 112 may include a material with a low coefficient of thermal expansion and a low ratio of dielectric tangent (Df) to dielectric constant (Dk). The dielectric layer may be substantially continuous across the bottom side of the bridge die layer 110 or other conductor layer 114 (i.e., where multiple dielectric and conductor layers are provided). However, interconnects or vias 134 may be provided through the dielectric layer 112 at one or more pads 128 of the bridge die and at the pillar 132 locations of the bridge die layer 110. Where multiple dielectric layers 112 and conductor layers 114 are provided, the vias may be located to provide for redistribution and may not align with the conductors extending out of the bridge die layer. In any case, at the locations of the vias 134, a respective portion of the dielectric layer 112 may be omitted for the full thickness of the dielectric layer 112. In one or more embodiments, the diameter of the vias 134 in the dielectric layer may be equal to or smaller than the diameter of the corresponding pads, pillars, or vias extending from the adjacent layer. Still further, in one or more embodiments, the vias 134 in the dielectric layer 112 may be conically shaped. Moreover, the diameter or crossing dimension 136 of the vias 134 on the bridge die side of the dielectric layer may be smaller than the diameter or crossing dimension 138 of the vias 134 further from the bridge die layer. Said another way, the vias 134 may include a taper from a first dimension 138 distal from the bridge layer 110 to a second, smaller dimension 136 proximal to the bridge layer 110. This taper may be the result of an etching or laser drilling process that acts from a particular side of the layer (e.g., the side with the wider dimension). The vias in the dielectric layer 112 may be filled with a conductor or metal, such as titanium-copper, for example, allowing for electrical communication through the dielectric layer 112 at selected locations that are aligned with the bridge die pads 128, die bumps 120, or other redistributed conductor locations.

The conductor layer 114 may be arranged below and adjacent to the dielectric layer 112 and/or between the bump layer 116 and the bridge die layer 110. The conductor layer 114 may be configured to provide circuit routing to contact points suitable for a selected power supply board or other board. The conductor layer 114 may be substantially continuous across the bottom side of the dielectric layer 112. However, circuit redistribution components and interconnects or vias 140 may be provided through the conductor layer 114. In one or more embodiments, a redistribution circuit trace 142 may be present in the conductor layer 114 and adjacent the dielectric layer 112 so as to allow the redistribution circuit trace 142 to interface with the vias 134 of the dielectric layer 112. The redistribution circuit trace 142 may have a thickness smaller than the overall thickness of the conductor layer 114 as shown. That is, the redistribution circuit trace 142 may have a thickness of approximately half of the thickness of the conductor layer 114. Interconnects or vias 140 may extend downward from the redistribution circuit trace 142 the remaining distance from the redistribution circuit trace 142 to the bottom side of the conductor layer 114. At the locations of the redistribution circuit trace 142 and the vias 140, a respective portion of the conductor layer 114 may be omitted for a portion of the thickness of the conductor layer 114. Still further, in one or more embodiments, all or a portion of the vias 134 in the conductor layer 114 may be conically shaped. That is, a diameter or crossing dimension 144 of the vias 140 at the bottom side of the redistribution circuit trace 142 may be smaller than the diameter or crossing dimension 146 of the vias 140 further from the dielectric layer 112. Said another way, the vias 140 may include a taper from a first dimension 146 distal from the bridge layer 110 and/or dielectric layer 112 to a second, smaller dimension 144 closer to the bridge layer 110 and/or the dielectric layer 112. The redistribution circuit trace 142 and the vias 140 in the conductor layer 114 may include a conductor or metal such as, for example, titanium-copper allowing for electrical communication into the conductor layer 114 at selected locations that are aligned with the vias 134 in the dielectric layer 112 and thus aligned with bridge die pads 128, die bumps 120 or other redistributed conductors.

As mentioned, the multi-die package may also include a power bump layer 116. This layer may be adapted to allow the multi-die package to be electrically coupled to a power supply board or other substrate 50, for example. The bump layer 116 may include bump plates 148 arranged on the interconnects or vias 140 extending downward out of the conductor layer 114. The bump plates 148 may include a copper-nickel-tin alloy or another suitable bump material may be provided. The power supply board bump layer 116 may allow the multi-die package 100 to be secured to a power supply board or other substrate 50 using thermal compression bonding or another bonding process may be used.

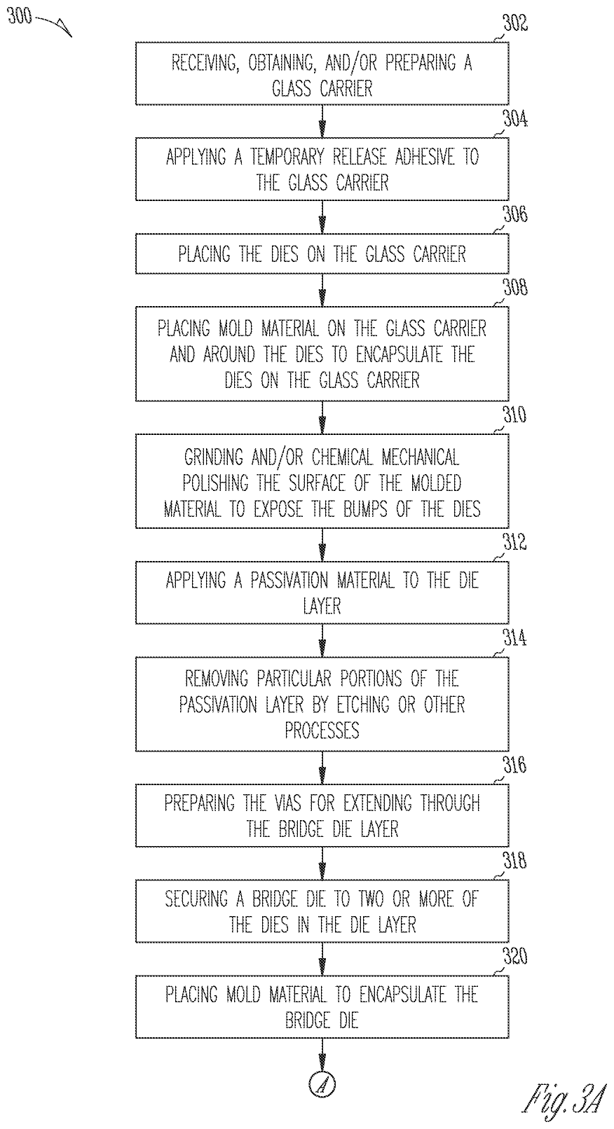

Turning now to FIGS. 3A and 3B, a method 300 of manufacturing may be provided. In particular, the method may include a die-first method where the die package is built in an inverted orientation so as to build the die package from the top down, so to speak. This particular approach to construction of the die-package may result in one or more of the structural or geometrical features discussed above. For example, the solder-free electrical pathway between the dies and the redistribution layer and/or the inverted conical nature of the interconnects or vias may result from this process. Reference to FIGS. 4-14 that show various stages of the manufacturing process may be made during the description of the method. Moreover, and in view of the inverted nature of the manufacturing process, terms like top, bottom, below, above, etc. may have a meaning that is the opposite of the meaning of those terms used with respect to FIGS. 1 and 2 and, instead, may reflect the orientation shown in FIGS. 4-14.

As shown in FIGS. 3A and 3B, the method may include receiving, obtaining, and/or preparing a glass carrier 58 (302). The glass carrier 58 may be used as a manufacturing substrate and/or template for constructing the multi-die package and/or several multi-die packages at one time. The glass carrier 58 may have a coefficient of thermal expansion (CTE) that is relatively close to silicon and ranging from approximately 2 to approximately 6 ppm/° C., or from approximately 3 to approximately 5 ppm/° C., or a CTE of approximately 4 ppm/° C. may be provided. In one or more embodiments, the glass carrier may include silicon dioxide glass.

As shown in FIG. 4, in one or more embodiments, the glass carrier 58 may include a temporary release adhesive 60 or the method may include applying a temporary release adhesive 60 to the glass carrier 58 (304). The temporary release adhesive 60 may be adapted to secure two or more dies 102 in selected relative positions and hold the dies 102 in place during a molding process. The temporary release adhesive 60 may be relatively thin and uniform. For example, the adhesive may have a thickness ranging from approximately 10 μm to approximately 20 μm. In one or more embodiments, the adhesive 60 may be an ultraviolet (UV) release, for example. While a temporary release adhesive 60 has been described, additional or alternative approaches to securing the dies 102 to the carrier 58 during molding may be provided. For example, silicon dioxide bonding or vacuuming methods may be used to secure the position of the dies 102 to the glass carrier 58.

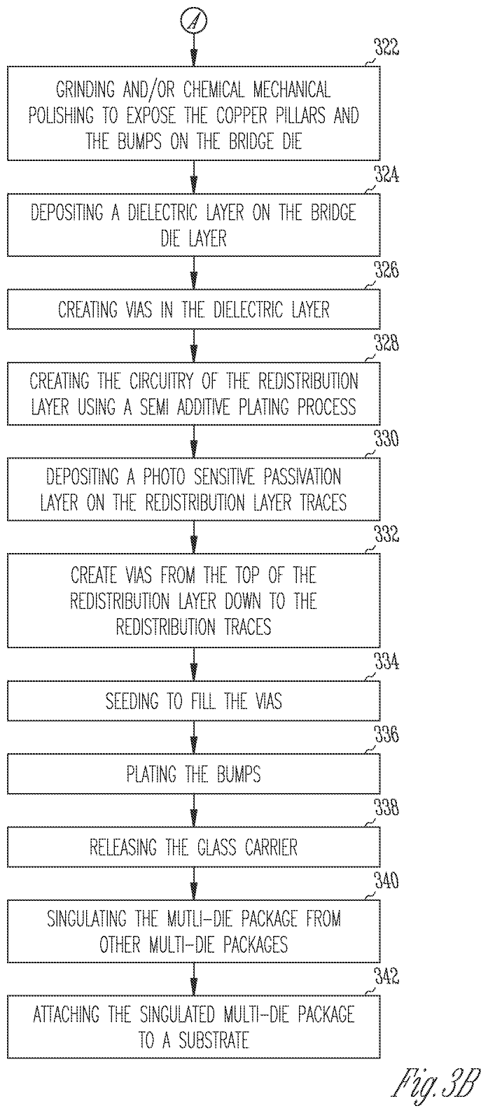

The method may also include creating a die layer 106 by placing the dies 102 on the glass carrier 58 (306). As shown in FIG. 5, the dies 102 may be placed with bumps 120 facing up and/or away from the glass carrier 58. In one or more embodiments, approaches that are used for attaching dies 102 in an upright manner may be used for assisting with proper placement of the dies 102 on the glass carrier 58. For example, in one or more embodiments, fiducials or other relative location marking elements may be provided on the surface of the glass carrier 58. These fiducials may be relied on for establishing markers, boundaries, or other guideposts for placing the dies 102 and/or for deposition and/or removal of material, for example. In one or more embodiments, these fiducials may be present on the glass carrier 58 prior to performance of the present method or the fiducials may be printed or otherwise placed on the glass carrier as part of the method.

The method may also include further creation of the die layer by placing encapsulating material 118 on the glass carrier 58 and around the dies 102 to encapsulate the dies 102 on the glass carrier 58 (308). As shown in FIG. 6, the encapsulating material 118 may flow onto the surface of the dies 102 and between the dies 102 and may flow in between and surround the bumps 120 on the dies 102 to a depth potentially deeper than the bumps 120 or close to or flush with a top surface of the bumps 120. The molding process may also include grinding the surface of the molded material 118 to expose the bumps 120 of the dies 102 and may also include chemical mechanical planarization or polishing to expose and/or reveal a top portion of the bumps 120 on the dies 102 above the mold material 118 (310). In one or more embodiments, the mold material 118 may be poured onto the surface of the glass carrier 58, injected, or otherwise placed to surround the dies 102 on the glass carrier 58.

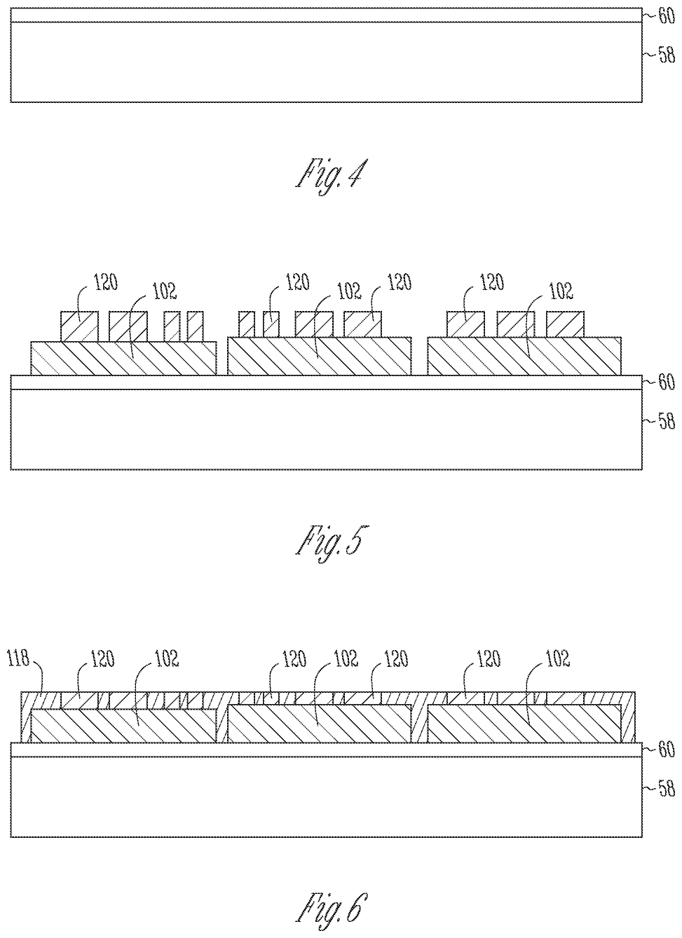

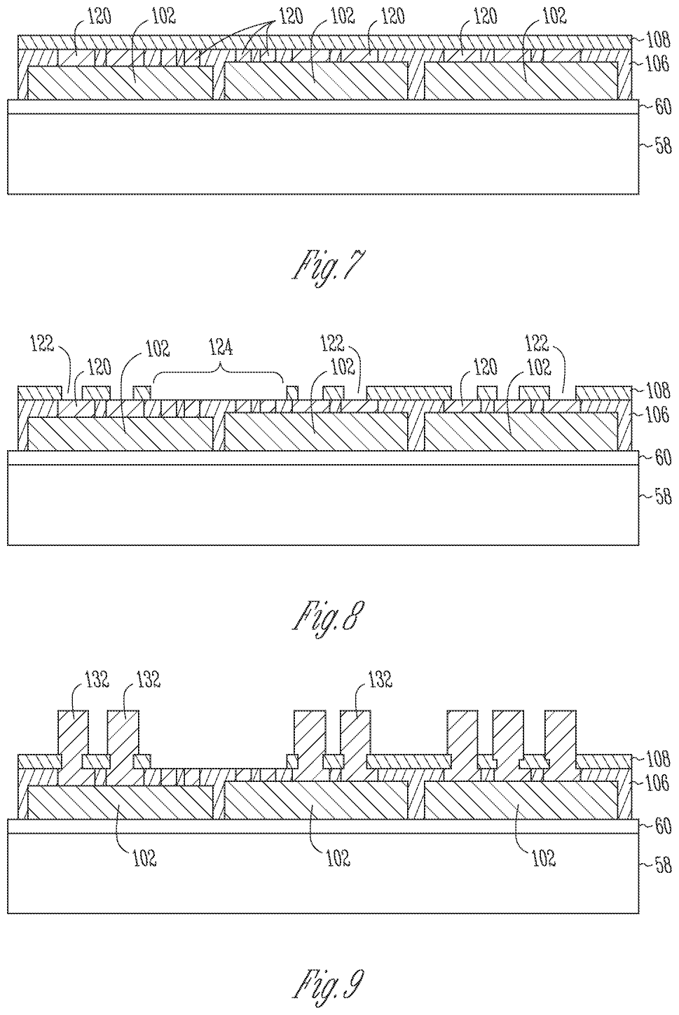

The method may also include creating a passivation layer 108 by applying a passivation material to the die layer 106 (312). The passivation layer 108 may be poured, injected, or otherwise deposited on the die layer 106 to substantially cover the die layer 106 as shown in FIG. 7. For purposes of providing electrical access to the bumps 120 on the dies 102 in the die layer 106, particular portions of the passivation layer 108 may be removed by etching or other processes (314). For example, and as shown in FIG. 8, a resist process may be used to create a pattern and dry etch vias or interconnects 122 in the passivation layer at the die bump locations to allow for power and input/output connections. In this particular case, the diameter or crossing dimension of the vias 122 created in the passivation layer 108 may be smaller than or equal to the diameter or crossing dimension of the die bumps 120. In one or more embodiments, the fiducials on the glass surface may be relied on by, for example, an exposure tool camera, for aligning the vias 122 in the passivation layer 108 with the die bumps 120. In addition to vias 122 aligned with the die bumps 120, a clearance area 124 for the bridge die 104 may also be created as part of the etching process.

The method may also include preparing the vias for extending through the bridge die layer (316). That is, as shown in FIG. 9, the method may include sputter depositing titanium copper seed on the passivation layer 108 and the vias 122 extending through the passivation layer 108. A photoresist may be used to form pillars 132 that may extend through the bridge die layer 110 from the vias 122 in the passivation layer 108. The height of the pillars 132, for example, may be selected to accommodate the thickness of the bridge die 104. Once the pillars 132 are formed, the photoresist may be stripped and the titanium copper seed may be etched leaving the pillars 132 extending from the vias 122 of the passivation layer 108.

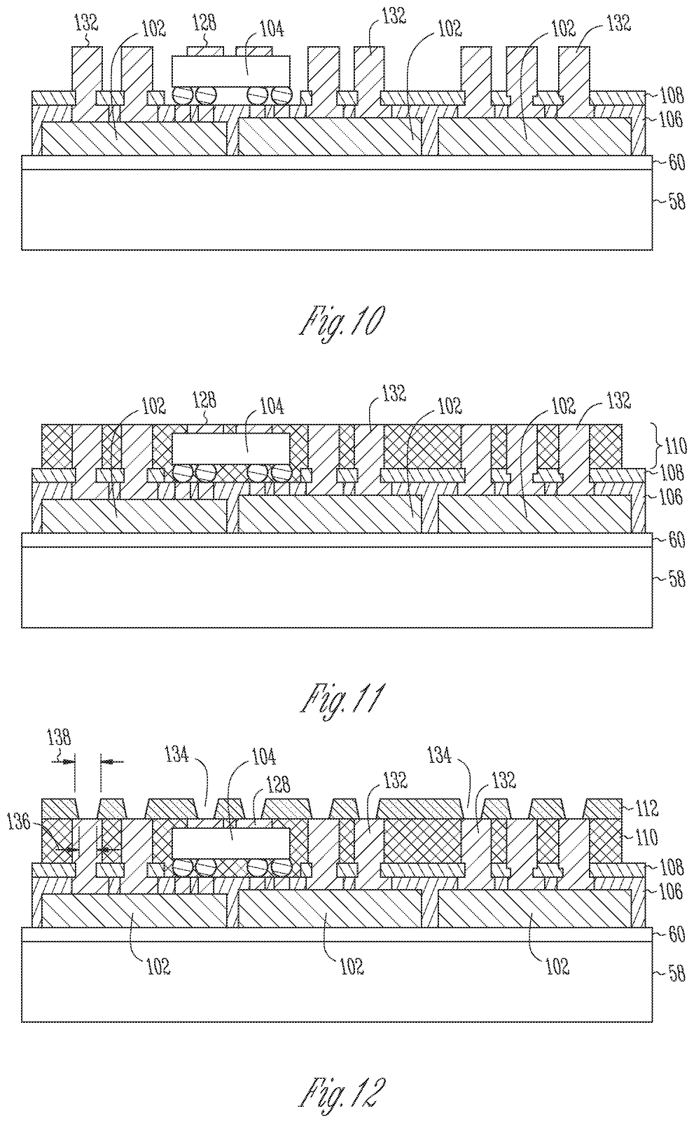

The method may also include forming the bridge die layer 110. For example, as shown in FIG. 10, a bridge die 104 may be secured in the clearance area 124 to two or more of the dies 102 in the die layer 106 using thermal compression bonding (318). As shown in FIG. 11, the bridge die layer 110 may then be molded to encapsulate the bridge die 104 including flowing under and around the bridge die 104 and on top of the bridge die 104 (320). The bridge die layer 106 may then be ground down and chemically mechanically polished to expose the copper pillars 132 and the pads 128 on the bridge die 104 (322).

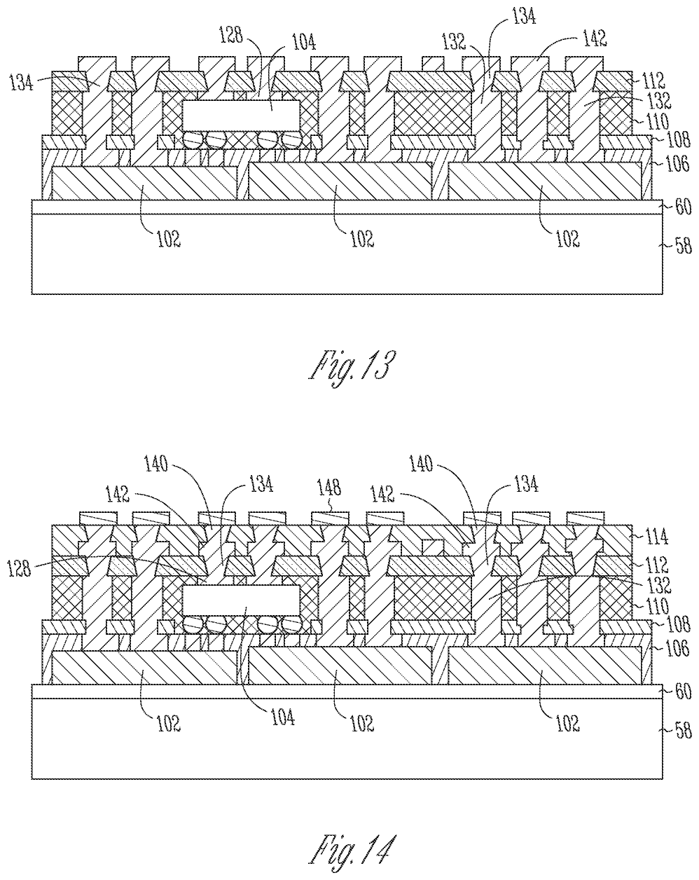

The method may also include forming the redistribution layer 111 by forming one or more dielectric and conductor layers 112/114. That is, as shown in FIG. 12, a dielectric layer 112 may be deposited on the bridge die layer 110 (324) and vias 134 may be created in the dielectric layer 112 using a substrate laser drill (326). A desmear process may be used to remove the debris from the drill holes. As shown and as a result of the laser drilling process, the vias 134 in the dielectric layer 112 may be conically shaped with a top having a larger diameter or crossing dimension 138 than the bottom diameter or crossing dimension 136.

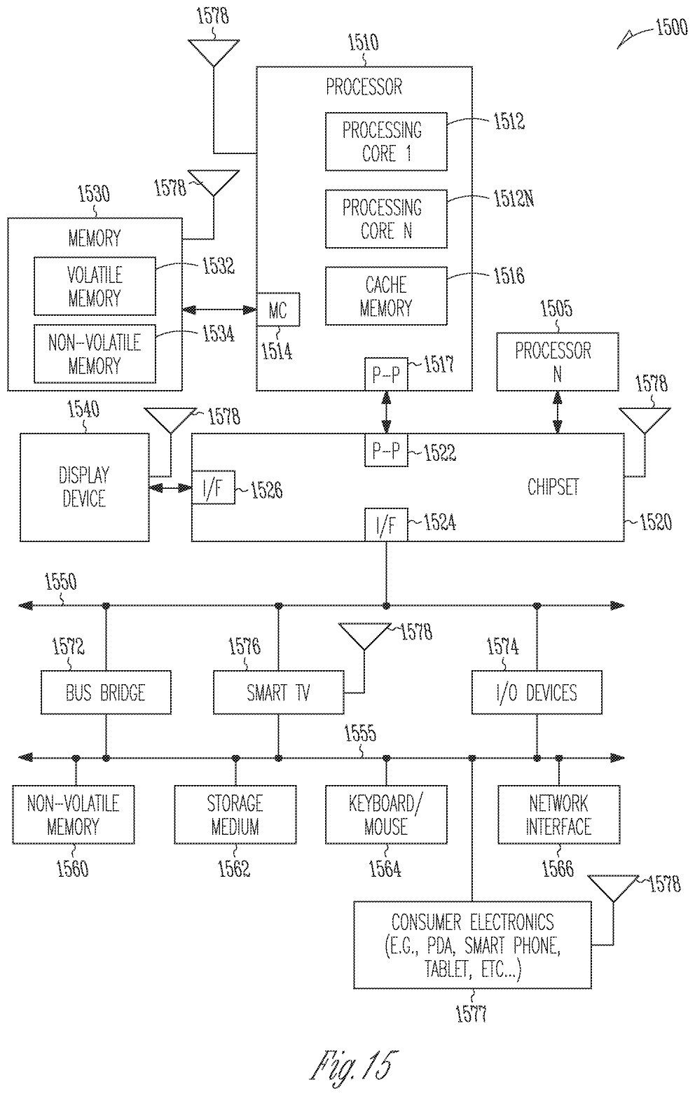

The method may also include creating the conductor layer 114. That is, as shown in FIG. 13, the redistribution circuit trace 142 of the conductor layer 114 may be created using a semi additive plating process (328). For example, a seed may be sputtered followed by patterning and electrolytic plating to fill the vias and plate the via pads as well to create the redistribution layer traces. The conductor layer 114 may be completed by depositing a photo sensitive passivation layer on the redistribution circuit traces 142 (330). As shown in FIG. 14, the photo sensitive passivation layer may cover the redistribution circuit traces 142 and may have a thickness approximately double the thickness of the redistribution circuit traces 142. A substrate laser drill and a desmear process may, again, be used to create vias 140 from the top of the conductor layer 114 down to the redistribution circuit traces 142 (332). Alternatively, a PID process with lithographic defined vias may be used or lithographic vias, plates, and then emasculation with dielectric and planarization may also be used. As shown, the vias 140 from the top of the conductor layer 114 down to the redistribution circuit trace 142 may have a larger diameter or crossing dimension 146 at the top than at the diameter or crossing dimension 144 at the bottom and the vias 140 may be tapered and may be conically shaped. The conductor layer 114 may be completed by seeding to fill the vias 140 (334) and a copper-nickel-tin alloy may be used to plate the bumps (336).

The method may also include releasing the glass carrier (338). That is, as shown in FIG. 2, and depending on the nature of the adhesive 60 used, the glass carrier 58 may be debonded. Where, for example, a UV adhesive is used, the glass carrier 58 may be exposed to a UV light to remove the glass carrier 58 from the multi die package 100.

The method may also include singulation. That is, while the present application depicts a single multi-die package 100 with three dies 102 and one bridge die 104, many packages may be created on the glass carrier 58 at the same time and the packages may be singulated by cutting the several die packages into individual packages (340).

The method may also include attaching the singulated multi-die package to a substrate 50 using thermal compression bonding (342). As shown in FIG. 1, the multi-die package 100 may be underfilled with epoxy 54. Polymer thermal interface materials may be provided, an integrated heat spreader (IHS) lid 52 may be provided, and a ball grid array 56 may be provided on the substrate.

FIG. 15 illustrates a system level diagram, depicting an example of an electronic device (e.g., system) that may include a multi-die package such as the package described above and/or a multi-die package manufactured using one or more of the methods described above. In one embodiment, system 1500 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 1500 includes a system on a chip (SOC) system.

In one embodiment, processor 1510 has one or more processor cores 1512 and 1512N, where 1512N represents the Nth processor core inside processor 1510 where N is a positive integer. In one embodiment, system 1500 includes multiple processors including 1510 and 1505, where processor 1505 has logic similar or identical to the logic of processor 1510. In some embodiments, processing core 1512 includes, but is not limited to, pre-fetch logic to fetch instructions, decode logic to decode the instructions, execution logic to execute instructions and the like. In some embodiments, processor 1510 has a cache memory 1516 to cache instructions and/or data for system 1500. Cache memory 1516 may be organized into a hierarchal structure including one or more levels of cache memory.

In some embodiments, processor 1510 includes a memory controller 1514, which is operable to perform functions that enable the processor 1510 to access and communicate with memory 1530 that includes a volatile memory 1532 and/or a non-volatile memory 1534. In some embodiments, processor 1510 is coupled with memory 1530 and chipset 1520. Processor 1510 may also be coupled to a wireless antenna 1578 to communicate with any device configured to transmit and/or receive wireless signals. In one embodiment, an interface for wireless antenna 1578 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 1532 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 1534 includes, but is not limited to, flash memory, phase change memory (PCM), read-only memory (ROM), electrically erasable programmable read-only memory (EEPROM), or any other type of non-volatile memory device.

Memory 1530 stores information and instructions to be executed by processor 1510. In one embodiment, memory 1530 may also store temporary variables or other intermediate information while processor 1510 is executing instructions. In the illustrated embodiment, chipset 1520 connects with processor 1510 via Point-to-Point (PtP or P-P) interfaces 1517 and 1522. Chipset 1520 enables processor 1510 to connect to other elements in system 1500. In some embodiments of the example system, interfaces 1517 and 1522 operate in accordance with a PtP communication protocol such as the Intel® QuickPath Interconnect (QPI) or the like. In other embodiments, a different interconnect may be used.

In some embodiments, chipset 1520 is operable to communicate with processor 1510, 1505N, display device 1540, and other devices, including a bus bridge 1572, a smart TV 1576, I/O devices 1574, nonvolatile memory 1560, a storage medium (such as one or more mass storage devices) 1562, a keyboard/mouse 1564, a network interface 1566, and various forms of consumer electronics 1577 (such as a PDA, smart phone, tablet etc.), etc. In one embodiment, chipset 1520 couples with these devices through an interface 1524. Chipset 1520 may also be coupled to a wireless antenna 1578 to communicate with any device configured to transmit and/or receive wireless signals. In one example, any combination of components in a chipset may be separated by a continuous flexible shield as described in the present disclosure.

Chipset 1520 connects to display device 1540 via interface 1526. Display 1540 may be, for example, a liquid crystal display (LCD), a light emitting diode (LED) array, an organic light emitting diode (OLED) array, or any other form of visual display device. In some embodiments of the example system, processor 1510 and chipset 1520 are merged into a single SOC. In addition, chipset 1520 connects to one or more buses 1550 and 1555 that interconnect various system elements, such as I/O devices 1574, nonvolatile memory 1560, storage medium 1562, a keyboard/mouse 1564, and network interface 1566. Buses 1550 and 1555 may be interconnected together via a bus bridge 1572.

In one embodiment, mass storage device 1562 includes, but is not limited to, a solid state drive, a hard disk drive, a universal serial bus flash memory drive, or any other form of computer data storage medium. In one embodiment, network interface 1566 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 15 are depicted as separate blocks within the system 1500, the functions performed by some of these blocks may be integrated within a single semiconductor circuit or may be implemented using two or more separate integrated circuits. For example, although cache memory 1516 is depicted as a separate block within processor 1510, cache memory 1516 (or selected aspects of 1516) can be incorporated into processor core 1512.

To better illustrate the method and apparatuses disclosed herein, a non-limiting list of embodiments is provided here:

Example 1 includes a semiconductor device, comprising two semiconductor dies, a redistribution layer, an interconnect bridge coupled between the two semiconductor dies and located vertically between the two semiconductor dies and the redistribution layer, and a metallic connection passing through the redistribution layer and coupled to one or more of the two semiconductor dies in a solder-free connection.

Example 2 includes the semiconductor device of example 1, wherein the metallic connection tapers from a first dimension distal from the two semiconductor dies to a second, smaller dimension at a location more proximal to the two semiconductor dies.

Example 3 includes the semiconductor device of any of examples 1 and 2 and further comprises a vertical interconnect coupled to the interconnect bridge through the redistribution layer, wherein the vertical interconnect tapers from a first dimension distal from the bridge to a second, smaller dimension more proximal to the bridge.

Example 4 includes the semiconductor device of any of examples 1-3, wherein the redistribution layer comprises a dielectric layer adjacent to the interconnect bridge and a conductor layer.

Example 5 includes the semiconductor device of example 4, wherein the vertical interconnect tapers from the first dimension to the second, smaller dimension as the vertical interconnect passes through the conductor layer and tapers from the first dimension to the second, smaller dimension as the vertical interconnect passes through the dielectric layer.

Example 6 includes the semiconductor device of any of examples 1-5, and further comprises a passivation layer between the two semiconductor dies and the interconnect bridge.

Example 7 includes the semiconductor device of any of examples 1-6, wherein the connection between the interconnect bridge and the two semiconductor dies is a solder connection.

Example 8 includes the semiconductor device of any of examples 4-5, wherein the conductor layer comprises redistribution circuit traces.

Example 9 includes the semiconductor device of any of examples 1-8, and further comprises a third semiconductor die.

Example 10 includes the semiconductor device of any of examples 1-9, wherein the interconnecting bridge is arranged in a bridge die layer and the metallic connection passes through the bridge die layer with a copper pillar.

Example 11 includes a system, comprising two semiconductor dies including a processor, a redistribution layer, an interconnect bridge coupled between the two semiconductor dies and located vertically between the two semiconductor dies and the redistribution layer, and a metallic connection passing through the redistribution layer and coupled to one or more of the two semiconductor dies in a solder-free connection. The system also comprises a storage medium and a bus coupled between the processor and the storage medium.

Example 12 includes the system of example 11, wherein the metallic connection tapers from a first dimension distal from the two semiconductor dies to a second, smaller dimension at a location more proximal to the two semiconductor dies.

Example 13 includes the system of any of examples 11-12 and further comprises a vertical interconnect coupled to the interconnect bridge through the redistribution layer, wherein the vertical interconnect tapers from a first dimension distal from the bridge to a second, smaller dimension more proximal to the bridge.

Example 14 includes the system of any of examples 11-13, wherein the redistribution layer comprises a dielectric layer adjacent to the interconnect bridge and a conductor layer.

Example 15 includes the system of example 14, wherein the vertical interconnect tapers from the first dimension to the second, smaller dimension as the vertical interconnect passes through the conductor layer and tapers from the first dimension to the second, smaller dimension as the vertical interconnect passes through the dielectric layer.

Example 16 includes a method of manufacturing a multi-die semiconductor package, comprising placing two semiconductor dies on a carrier with bumps facing up, coupling a bridge die between the two semiconductor dies using a first subset of the bumps, extending a second subset of the bumps upward with pillars to match a height of the bridge die, depositing one or more conductor layers with redistribution circuit traces across the pillars and the bridge die, placing bumps on the redistribution layer.

Example 17 includes the method of claim 16, wherein the conductor layer is thicker than the redistribution circuit traces and the method further comprises creating vias from the redistribution circuit traces to a surface of the conductor layer.

Example 18 includes the method of claim 17, wherein creating vias in the conductor layer comprises laser drilling to form conical vias that have a first dimension at the surface and a second smaller dimension at the redistribution circuit trace.

Example 19 includes the method of any of claims 16-18 and further comprises releasing the carrier.

Example 20 includes the method of any of claims 16-19 and further comprises attaching the multi-die semiconductor package to a substrate.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the inventive subject matter has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

The terminology used in the description of the example embodiments herein is for the purpose of describing particular example embodiments only and is not intended to be limiting. As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context.

What is claimed is:

1. A semiconductor device, comprising:
two semiconductor dies;
a redistribution layer;
an interconnect bridge coupled between the two semiconductor dies and located vertically between the two semiconductor dies and the redistribution layer; and
a metallic connection passing through the redistribution layer and coupled to one or more of the two semiconductor dies in a solder-free connection.

2. The semiconductor device of claim 1, wherein the metallic connection tapers from a first dimension distal from the two semiconductor dies to a second, smaller dimension at a location more proximal to the two semiconductor dies.

3. The semiconductor device of claim 1, further comprising a vertical interconnect coupled to the interconnect bridge through the redistribution layer, wherein the vertical interconnect tapers from a first dimension distal from the bridge to a second, smaller dimension more proximal to the bridge.

4. The semiconductor device of claim 3, wherein the redistribution layer comprises a dielectric layer adjacent to the interconnect bridge and a conductor layer.

5. The semiconductor device of claim 4, wherein the vertical interconnect tapers from the first dimension to the second, smaller dimension as the vertical interconnect passes through the conductor layer and tapers from the first dimension to the second, smaller dimension as the vertical interconnect passes through the dielectric layer.

6. The semiconductor device of claim 1, further comprising a passivation layer between the two semiconductor dies and the interconnect bridge.

7. The semiconductor device of claim 1, wherein the connection between the interconnect bridge and the two semiconductor dies is a solder connection.

8. The semiconductor device of claim 1, wherein the conductor layer comprises redistribution circuit traces.

9. The semiconductor device of claim 1, further comprising a third semiconductor die.

10. The semiconductor device of claim 1, wherein the interconnecting bridge is arranged in a bridge die layer and the metallic connection passes through the bridge die layer with a copper pillar.

11. A system, comprising:
two semiconductor dies including a processor;
a redistribution layer;
an interconnect bridge coupled between the two semiconductor dies and located vertically between the two semiconductor dies and the redistribution layer;
a metallic connection passing through the redistribution layer and coupled to one or more of the two semiconductor dies in a solder-free connection;
a storage medium; and
a bus coupled between the processor and the storage medium.

12. The system of claim 11, wherein the metallic connection tapers from a first dimension distal from the two semiconductor dies to a second, smaller dimension at a location more proximal to the two semiconductor dies.

13. The system of claim 11, further comprising a vertical interconnect coupled to the interconnect bridge through the redistribution layer, wherein the vertical interconnect tapers from a first dimension distal from the bridge to a second, smaller dimension more proximal to the bridge.

14. The system of claim 13, wherein the redistribution layer comprises a dielectric layer adjacent to the interconnect bridge and a conductor layer.

15. The system of claim 14, wherein the vertical interconnect tapers from the first dimension to the second, smaller dimension as the vertical interconnect passes through the conductor layer and tapers from the first dimension to the second, smaller dimension as the vertical interconnect passes through the dielectric layer.

16. A method of manufacturing a multi-die semiconductor package, comprising:
placing two semiconductor dies on a carrier with bumps facing up;
coupling a bridge die between the two semiconductor dies using a first subset of the bumps;
extending a second subset of the bumps upward with pillars to match a height of the bridge die;
depositing one or more conductor layers with redistribution circuit traces across the pillars and the bridge die; and
placing power supply bumps on the redistribution layer.

17. The method of claim 16, wherein the conductor layer is thicker than the redistribution circuit traces and the method further comprises creating vias from the redistribution circuit traces to a surface of the conductor layer.

18. The method of claim 17, wherein creating vias in the conductor layer comprises laser drilling to form conical vias that have a first dimension at the surface and a second smaller dimension at the redistribution circuit trace.

19. The method of claim 16, further comprising releasing the carrier.

20. The method of claim 19, further comprising, attaching the multi-die semiconductor package to a substrate.
